(19) United States
(12) Patent Application Publication
(10) Pub. No.: US 2008/0088304 A1
(43) Pub. Date: Apr. 17, 2008

(54) Method and apparatus for measuring magnetic anisotropy of a conductive wire or tape

(76) Inventors: J. Yates Coulter, Santa Fe, NM (US); Leonardo Civale, Los Alamos, NM (US)

Correspondence Address: LOS ALAMOS NATIONAL SECURITY, LLC, LOS ALAMOS NATIONAL LABORATORY, PPO. BOX 1663, LC/IP, MS A187, LOS ALAMOS, NM, 87545, US

(21) Appl. No.: 11/881,192

(22) Filed: Jul. 25, 2007

Related U.S. Application Data
(60) Provisional application No. 60/833,200, filed on Jul. 25, 2006.

(51) Int. Cl. G01R 33/00

(52) U.S. Cl. 324/263

(57) ABSTRACT

A method and apparatus for measuring the magnetic field anisotropy of critical currents in conductive wires and conductive tapes having lengths of at least one meter. In one embodiment, the method and apparatus are adapted to measure the magnetic field anisotropy of critical currents in superconducting wires and tapes. The apparatus includes a magnetic field generation assembly that is capable of generating a magnetic field. The magnetic field is orthogonal to a current passing through a conductive wire or conductive tape positioned on an axis of the assembly. The magnetic field generation assembly and magnetic field are rotatable about the axis.

### RELATED APPLICATIONS

This application claims the benefit of provisional patent application Ser. No. 60/833,200, filed on Jul. 25, 2006.

### STATEMENT REGARDING FEDERAL RIGHTS

This invention was made with government support under Contract No. DE-AC 52-06 NA 25396, awarded by the U.S. Department of Energy. The government has certain rights in the invention.

### FIELD OF THE INVENTION

The present invention relates to an apparatus for determining the critical current in conductive wires and tapes that exhibit a critical current such as superconducting wires and tapes. Further, the present invention relates to a method for determining the magnetic anisotropy of the critical current in superconducting wires and tapes. Still further, the present invention relates to a method for identifying regions of superconducting wires and tapes having variations in superconductive properties that are casual to variations in critical currents.

### BACKGROUND OF THE INVENTION

Coated conductor technology that incorporates oxide superconducting films that comprise, for example, yttrium barium copper oxide (YBCO), bismuth strontium calcium copper oxide (BSSCO), and the like is progressing at a fast pace. The fabrication processes have been scaled up from bench-scale research methods that often worked on samples having a length of about 1 centimeter (cm). Second generation fabrication technology can now produce coated conductors (superconducting tapes) having lengths approaching the 1-kilometer range, such fabrication technology involving several deposition methods.

Currently there are two principal but differing techniques for producing coated conductors. The differing techniques involve a different substrate upon which are deposited various buffer layers and different rare earth based superconducting compounds. Even the critical current properties exhibited by these differing technologies are different.

The magnitude of the critical current, I_{c}, is the primary metric by which superconductor performance is evaluated. Critical current measurements on short (i.e., less than about 10 cm) samples of high-T_{c} superconductors, and have been carried out for many years. Measurement systems consist of a means for maintaining the sample at cryogenic temperatures, a means for applying a magnetic field, a means for rotating the sample around a vertical axis to measure the anisotropy of the I_{c}. The geometry of such a system results in the sample being mounted on a probe of 1-2 meters in length and inserted vertically downward into a Dewar flask or cooler with a tail section centered in the magnetic field. The cost of such a system can easily exceed $30,000-50,000 with a superconducting magnet system being the principal cost. Further, the size of such magnet systems typically result in a 2-4 square meter laboratory footprint.

It is not been clear whether the measurements for superconducting properties on short pieces of coated conductors (i.e., a few centimeters) can always successfully predict the superconducting properties of longer pieces of coated conductors (i.e., greater than a few hundred meters). As coated conductive tapes are fabricated in lengths that are sufficiently long (i.e., >1 meter) to enter service in applications such as power transmission and power generation, it is necessary to obtain the properties of shorter samples in the longer commercial lengths and to demonstrate these properties as a function of position on the conductive tape.

Position dependent I_{c} measurements along the length of a coated conductor in the absence of an applied magnetic field are presently used to demonstrate conductor uniformity. Variations in I_{c} are observed by both industrial and research institutions in long coated conductors. The causes of such variations remain largely unknown, but are assumed to result from variations in conductor cross-section area. Nondestructive techniques are needed to determine the position dependent superconductive characteristics along the length of the conductor with such techniques producing results consistent with results obtained in prior measurement systems. Then the results could be readily compared with results from measurements performed on shorter samples so as to provide insights into potential causes of the self-field I_{c} variations.

Thus, what is needed is an apparatus and a method of measuring the magnetic field anisotropy of such conductors having long—or ‘infinite’—lengths. Also, it is desirable to have a method of identifying regions having variations in superconducting properties within a long length of coated conductor.

Coated conductor films intrinsically carry less electrical current in applied magnetic fields, as the critical current of such materials is inversely proportional to the strength of an applied magnetic field. The critical current also exhibits magnetic anisotropy; i.e., the critical current varies when the magnetic field is applied at different angles to the current traveling through the conductor film. This effect is most interesting when the applied field is maintained at the Lorentz Force maximum orientation with the sample current perpendicular to the applied field.

### SUMMARY OF INVENTION

The present invention meets these and other needs by providing a method and apparatus for measuring the magnetic field anisotropy of critical currents in conductive wires and conductive tapes having lengths of at least one meter. In one embodiment, the method and apparatus are adapted to measure the magnetic field anisotropy of critical currents in superconducting wires and tapes. The apparatus includes a magnetic field generation assembly that is capable of generating a magnetic field that is orthogonal to a current passing through a conductive wire or conductive tape positioned on an axis of the assembly. The magnetic field generation assembly and magnetic field are rotatable about the axis.

Accordingly, one aspect of the invention is to provide an apparatus for measuring magnetic anisotropy of a conductive tape or a conductive wire. The apparatus comprises: a magnetic field generation assembly comprising a plurality of magnets that are fixed with respect to each other and rotatable about an axis, wherein the plurality of magnets is capable of generating a uniform magnetic field orthogonal to a direction of a current passing through a portion of the conductive wire or the conductive tape located along the axis, and wherein the uniform magnetic field is rotatable about the axis; a power supply electrically connected to the conductive wire or the conductive tape, wherein the power supply is capable of providing current to the conductive wire or the conductive tape; and a voltage measurement device capable of measuring a voltage between a first point and a second point of the conductive wire or the conductive tape, wherein the portion of the conductive wire or the conductive tape is located along the axis between the first point and the second point.

A second aspect of the invention is to provide a magnetic field generation assembly for measuring positionally dependent anisotropy of a conductive wire or a conductive tape. The magnetic field generation assembly comprises: a ring having an inner surface; and a pair of magnets disposed on the inner surface of the ring, wherein the pair of magnets are rotatable about an axis of the ring and are diametrically opposed to each other. The pair of magnets is capable of generating a uniform magnetic field orthogonal to a direction of a current in a portion of the conductive wire or the conductive tape disposed at the axis. The uniform magnetic field is rotatable about the axis and the direction of the current.

Another aspect of the invention is to provide an apparatus for measuring magnetic anisotropy of a conductive tape or a conductive wire. The apparatus comprises: a magnetic field generation assembly comprising a ring having an inner surface and a pair of magnets disposed on the inner surface of the ring, wherein the pair of magnets are diametrically opposed to each other and rotatable about an axis of the ring and, wherein the pair of magnets is capable of generating a uniform magnetic field orthogonal to a direction of a current in a portion of the conductive wire or the conductive tape disposed along the axis, and wherein the uniform magnetic field is rotatable about the axis; a power supply electrically connected to the conductive wire or the conductive tape, wherein the power supply provides the current through one of the conductive wire and the conductive tape; a voltage measurement device capable of measuring a voltage between a first point and a second point of the conductive wire or the conductive tape, wherein the portion of the conductive wire or the conductive tape is located along the axis between the first point and the second point; and an assembly for moving the conductive wire or the conductive tape through the magnetic field generation assembly.

Still another aspect of the invention is to provide a method of determining the magnetic anisotropy of a conductive wire or a conductive tape of unlimited length. The method comprises the steps of: positioning the conductive wire or the conductive tape in a magnetic field having a predetermined strength in a first orientation with respect to the magnetic field such that a current passing through the conductive wire or the conductive tape is orthogonal to the magnetic field; determining a first critical current of the conductive wire or conductive tape in the first orientation; positioning the conductive wire or the conductive tape at a second orientation relative to the magnetic field; determining a second critical current of the conductive wire or conductive tape in the second orientation; and comparing the first critical current to the second critical current to determine the magnetic anisotropy of the conductive wire or conductive tape.

Yet another aspect of the invention is to provide a method for detecting regions, within a conductive wire or conductive tape, having a critical current that varies from the average critical current by a predetermined value. The method includes: determining a magnetic field anisotropy of the critical current of the conductive wire or the conductive tape at a plurality of positions along a length of the conductive wire or conductive tape, wherein the regions can be identified within the conductive wire or the conductive tape as a function of position along the length; and locating the regions by detecting a predetermined variance in the magnetic field anisotropy measured at the plurality of positions. The predetermined variance can generally be where there is a difference of about 10 percent, although that difference may be lower such as 5 percent, 3 percent or even lower as quality of tape processing improves and even smaller differences are examined.

These and other aspects, advantages, and salient features of the present invention will become apparent from the following detailed description, the accompanying drawings, and the appended claims.

### BRIEF DESCRIPTION OF THE DRAWINGS

FIG. 1 is a schematic representation of an apparatus for determining the magnetic anisotropy of the critical current of a conductive wire or a conductive tape;

FIG. 2 is a detail of a the apparatus shown in FIG. 1;

FIG. 3a is a schematic representation of a magnetic field generation assembly that generates a magnetic field that is orthogonal to an axis;

FIG. 3b is a schematic representation of the magnetic field generation assembly shown in FIG. 3a rotated from by α degrees;

FIG. 4 is a schematic representation of a magnetic field generation assembly;

FIG. 5 is a flow chart for a method of determining the magnetic anisotropy of the critical current of a conductive wire or a conductive tape;

FIG. 6 is a flow chart for a method of determining critical current in a conductive wire or a conductive tape;

FIG. 7 is a flow chart for a method of locating critical current-enhancing structures in a conductive wire or a conductive tape; and

FIG. 8 is a plot showing an example of how critical current is determined from voltage and current data.

FIG. 9 is a plot showing position dependent I_{c} measurements B∥tape normal vector, on a 20 meter long conductor at 75 K and B≈0.52 T.

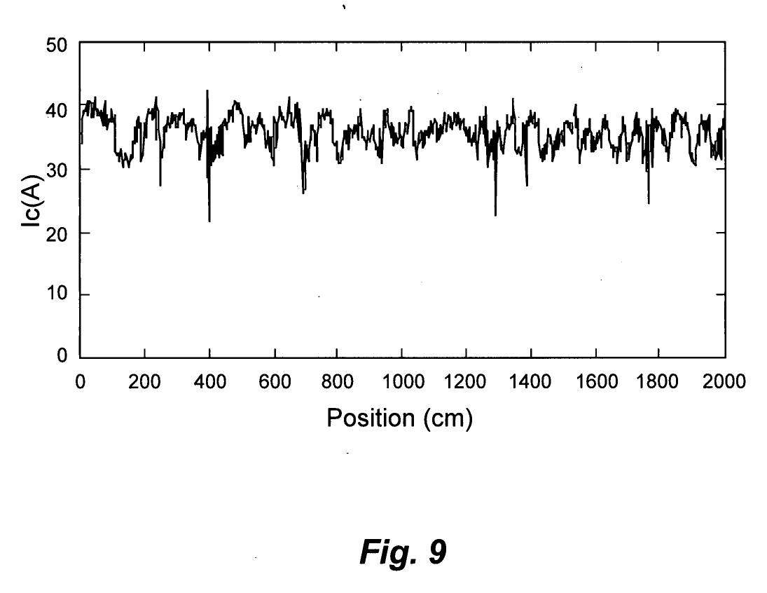

FIG. 10 is a plot showing angular I_{c} measurements made at two positions (x=397 cm arid X=399 cm) on the conductor at 75 K and B≈0.52 T.

FIG. 11 is a plot showing position dependent I_{c} measurements using magnetic fields, B∥tape normal vector and B∥tape plane, simultaneously applied at two positions to a conductor to characterize the anisotropy at 75 K and B≈0.52 T.

FIG. 12 is a plot showing angular I_{c} measurements made at five positions on the conductor to investigate variations in the anisotropy ratio seen in FIG. 11 at 75 K and B≈0.52 T.

FIG. 13 is a plot showing critical current values measured as a function of position, magnetic field B∥c and B∥tape plane and temperature of 75 K.

FIG. 14 is a plot showing critical current measurements made as function of magnetic field B∥c and position with a temperature of 75 K.

FIG. 15 is a plot showing a log/log chart of FIG. 14 of critical current measurements made as a function of magnetic field B∥c and position with a temperature of 75 K to demonstrate two different behaviors along a length of a superconductor shown in FIG. 13.

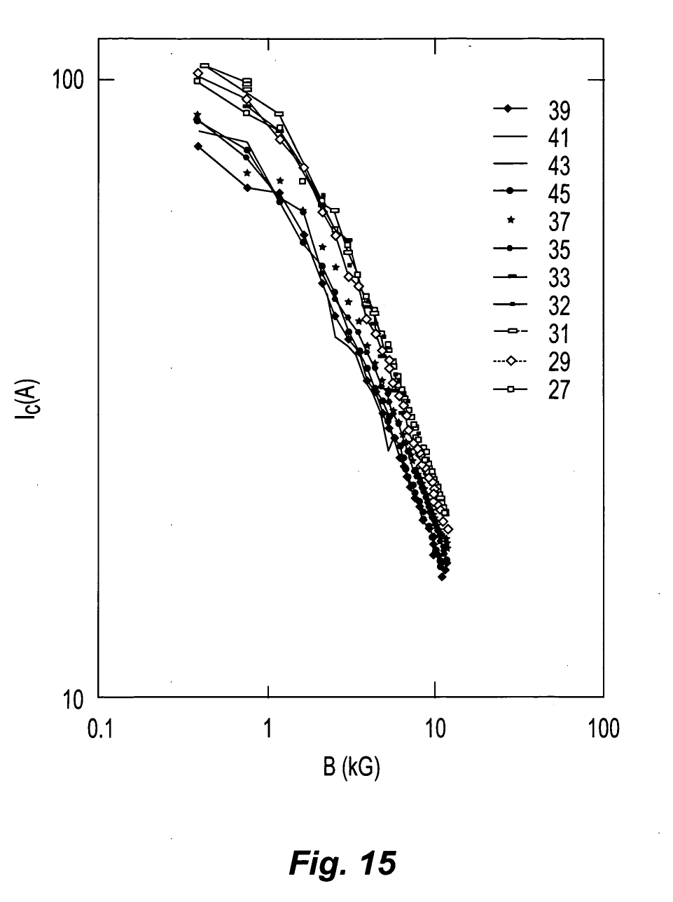

FIG. 16 is a plot showing critical current values measured as a function of position, magnetic field B∥c and B∥tape plane and temperature of 75 K.

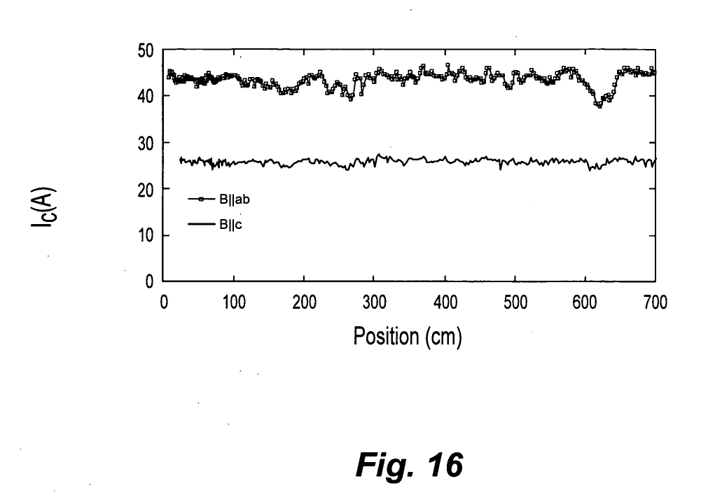

FIG. 17 is a plot showing angular I_{c} measurements made at five positions on the conductor to investigate variations in the anisotropy ratio seen in FIG. 11 at 75 K and B≈0.52 T.

FIG. 18 shows a schematic representation for determining the maximum conduction direction of anisotropic superconducting wire and optimizing the winding direction for conductivity of the superconductors in electrical applications.

FIG. 19 shows a schematic drawing of a solenoid with magnetic fields, and divergent flux lines.

FIGS. 20(a) and (b) show the control of Joule heating during I_{c} characterization with an applied field.

### DETAILED DESCRIPTION

In the following description, like reference characters designate like or corresponding parts throughout the several views shown in the figures. It is also understood that terms such as “top,” “bottom,” “outward,” “inward,” and the like are words of convenience and are not to be construed as limiting terms. In addition, whenever a group is described as either comprising or consisting of at least one of a group of elements and combinations thereof, it is understood that the group may comprise or consist of any number of those elements recited, either individually or in combination with each other.

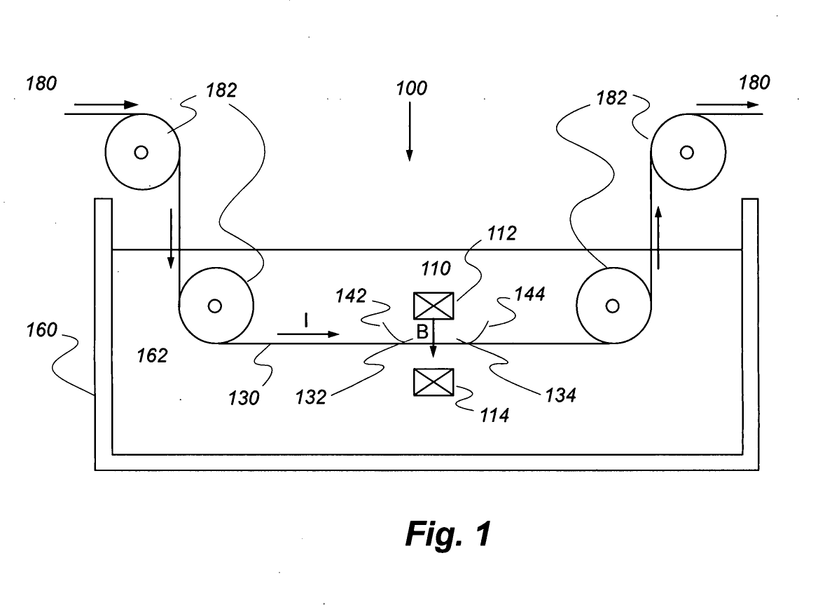

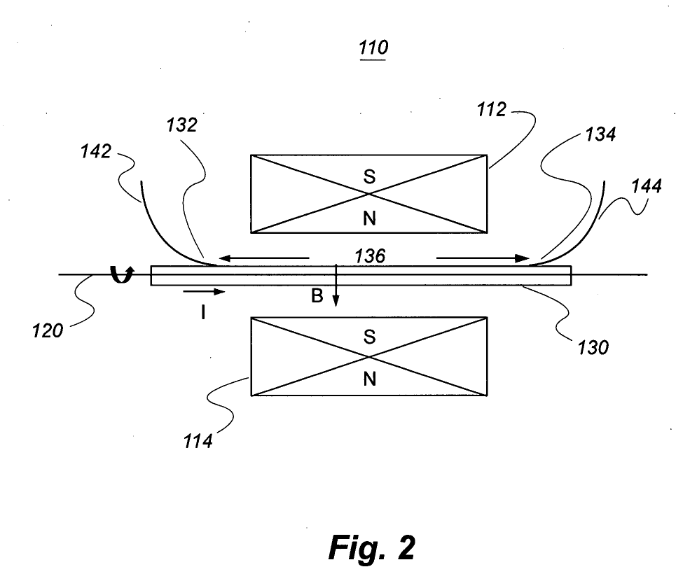

Referring to the drawings in general and to FIG. 1 in particular, it will be understood that the illustrations are for the purpose of describing a particular embodiment of the invention and are not intended to limit the invention thereto. Turning to FIG. 1, an apparatus 100 for measuring the magnetic anisotropy of a conductive wire or conductive tape is schematically shown. A portion of FIG. 1 is shown in detail in FIG. 2. Referring to both FIG. 1 and FIG. 2, apparatus 100 includes a magnetic field generation assembly 110 that comprises a plurality of magnets 112, 114 that are rotatable about an axis 120, which is parallel to both the direction of translation of the conductive wire or conductive tape 130 and current I passing through the conductive wire or conductive tape 130. Magnetic field generation assembly 110 generates a magnetic field B that is orthogonal to axis 120. Apparatus 100 also includes a power supply (not shown) that is capable of supplying a current I through conductive tape or conductive wire 130, which is positioned along axis 120. A portion 136 of conductive wire or conductive tape 130 is located along axis 120 between magnets 112, 114 and within magnetic field B. Voltage taps 142 and 140 permit a voltage measurement device (not shown) that is capable of measuring the voltage between a first point 132 and a second point 134 on conductive wire or tape 130. As seen in FIG. 2, portion 136 of conductive wire or conductive tape 130, which is located within magnetic field B, is included between first point 132 and second point 136.

Magnetic field generation assembly 110 comprises a plurality of magnets 112, 114. While only magnets 112 and 114 are shown in the various figures included herewith, it is understood that magnetic field generation assembly 110 may include additional magnets. Magnets 112, 114 are fixed with respect to each other such that the north pole of one magnet faces the south pole of the other magnet. In one embodiment, at least one of magnets 112, 114 is a rare earth magnet such, as but not limited to, neodymium-iron-boron magnets, aluminum-nickel-cobalt magnets, samarium-cobalt magnets, and the like. In another embodiment, at least one of magnets 112, 114 is an electromagnet. Magnets 112, 114 generate a magnetic field B of at least about 1 Tesla.

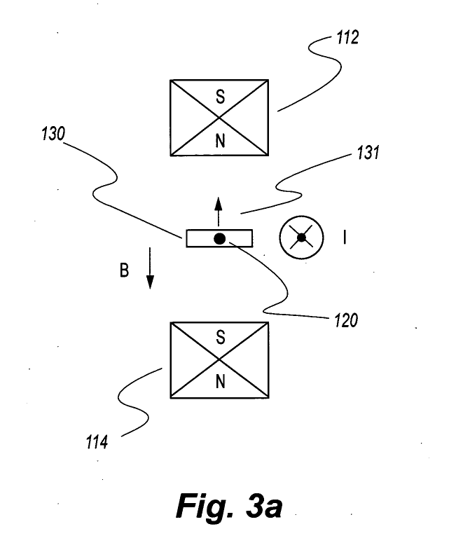

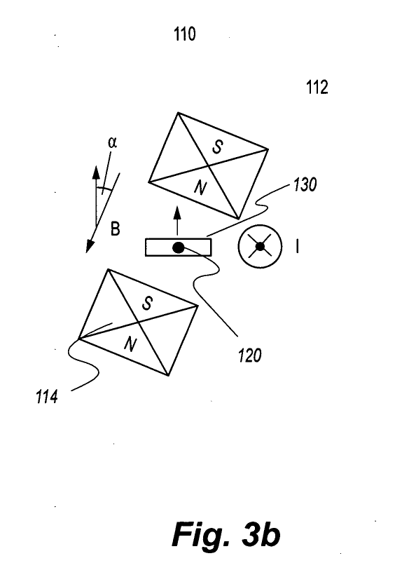

As previously described, magnetic field generation assembly 110 generates a magnetic field B that is orthogonal to axis 120 and current I, as shown in FIG. 3a. Magnetic field generation assembly 110 also enables magnets 112, 114- and magnetic field B—to be rotated about axis 120. In FIG. 3b, magnets 112, 114 and magnetic field B have been rotated from the position shown in FIG. 3a by a degrees.

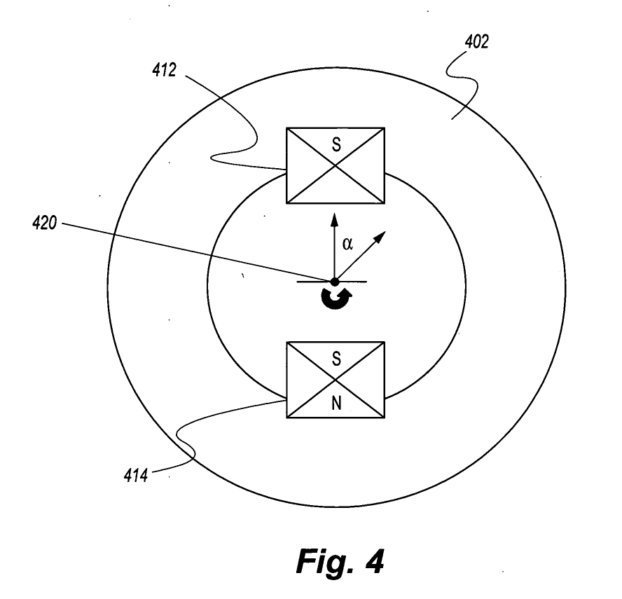

In one particular embodiment, schematically shown in FIG. 4, magnetic field generation assembly 410 comprises a retaining yoke or ring structure 402 having an inner surface 404. Magnets 412, 414 are disposed on inner surface 404 of ring 402 opposite each other such that the north pole of one magnet faces the south pole of the other magnet and the magnetic field generated by magnets 412, 414 passes through axis 420 of ring 402. Magnets 412, 414 and magnetic field B are rotatable about axis 420 of ring 402, and thus about the direction of a current I passing through conductive wire or conductive tape located along axis 420. To facilitate such rotation, magnetic field generation assembly 410 may further comprise a drive mechanism (not shown). Such a drive mechanism may be selected from those that are well known in the art, such as a tooth and gear assembly, worm gear drive, and the like. Here, the magnetic field generation assembly 410 is magnetically rotated about axis 420 (and the conductive wire or conductive tape) relative to the conductor normal. In one embodiment, a multi-solenoid electromagnetic system can be powered such that the magnetic field vector is the vectoral sum of the two components of the magnetic field. In another embodiment, the tape normal vector can be rotated relative to the applied magnetic field vector by mechanically twisting the conductive wire or conductive tape as it is translated through the applied magnetic field.

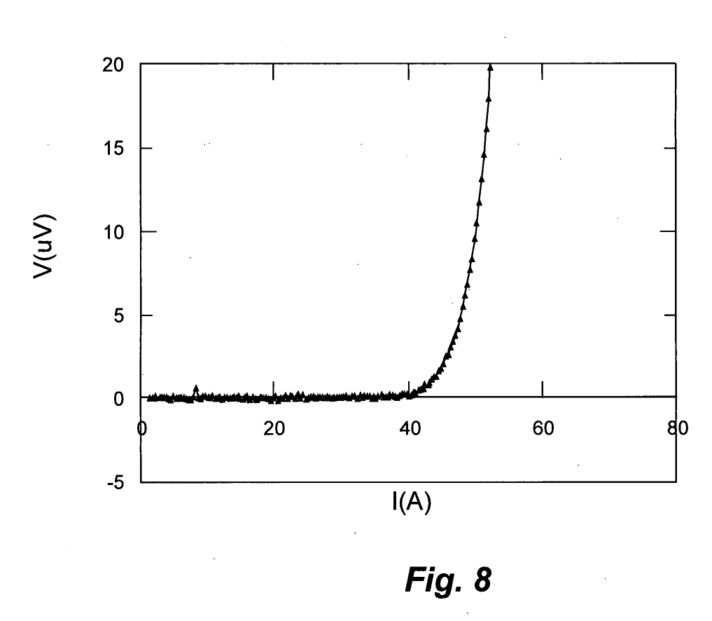

A power supply (not shown) is electrically coupled to conductive wire or conductive tape 130 to provide current I to a portion 136, which is located in magnetic field B and between first point 132 and second point 134 (FIGS. 1 and 2). The power supply is capable of providing a current to the conductive wire or the conductive tape 130 that is greater than or equal to the critical current of conductive wire or conductive tape 130. For the purpose of understanding the invention, the critical current is defined as the current required to dissipate a specified voltage across a region of conductive wire or conductive tape 130. FIG. 8 shows an example of how the critical current I_{c} is determined from the voltage across a conductor and current I. From the data shown in FIG. 8, the critical current I_{c} is determined to be about 48 amperes at 5 μV. The critical current is dependent in part upon the composition of conductive wire or tape 130. The critical current, for example, depends on whether or not conductive wire or tape 130 comprises a superconductor, and the type of superconductor (e.g., whether the superconductor is a bismuth oxide-based superconductor or a yttrium oxide based superconductor) present in conductive wire or conductive tape 130. The power supply may be one of a DC power supply, an AC power supply, and a pulse power supply.

A voltage measuring device is electrically coupled to first point 132 and second point 134 through voltage taps 142 and 144. The voltage measuring device is capable of measuring a voltage of about 1 nanovolt (nV) between first point 132 and second point 134. The voltage measuring device may include any such device known in the art that is capable of measuring voltages of this magnitude. An example of such a voltage measurement device is a Keithly™ model 2182 71/2 digital voltmeter or its equivalent.

Whereas previous attempts to measure the magnetic anisotropy of conductive wire or conductive tape have limited to tape segments of less that 10 cm in length, apparatus 100 is capable of conducting such measurements on continuous lengths of conductive wire or conductive tape 130 having a length of at least one meter. Accordingly, apparatus 100 may further comprise a payout/take up apparatus 180 that is capable of feeding continuous lengths of conductive wire or conductive tape 130 of at least one meter. Payout/take-up assembly 180 feeds conductive wire or conductive tape 130 from a source to apparatus 100 such that conductive wire or conductive tape 130 travels along axis 120 through magnetic field generation assembly 110, where it is exposed to magnetic field B. Payout/take-up assembly 180 may include a payout station (not shown), tensioning/positioning devices 182, such as, for example, rollers, and a take-up station (not shown). Various systems that are known in the art, such as capstan-rollers, cassettes, reel-to-reel assemblies, and the like, for feeding and taking up wire or tape may be employed in payout/take-up assembly 180.

It is frequently desirable to determine the magnetic anisotropy of superconducting wires or tapes. Such wires and tapes do not exhibit superconducting properties at room temperatures, and must therefore be cooled to and maintained at temperatures at which such properties are present. Accordingly, apparatus 100 may further include a low temperature bath 160 that is capable of cooling and maintaining magnetic field generation assembly 110 and portion 136 of conductive wire or tape 130 to a temperature at which conductive wire or conductive tape 130 exhibit superconducting properties. In one embodiment, low temperature bath 160 is adapted to contain a cryogenic liquid 162, such as liquid nitrogen, and is capable of cooling magnetic field generation assembly 110 and portion 136 of conductive wire or tape 130 to a temperature that is less than or equal to the boiling point of nitrogen.

In the embodiment shown in FIG. 1, apparatus 100 is oriented with respect to cryogenic bath 160 such that only a region close to portion 136 that is being characterized is immersed in cryogenic liquid 162. In another embodiment, apparatus 100 is oriented with respect to cryogenic bath such that the entire conductive wire or conductive tape 130 is immersed in cryogenic liquid 162.

A method of determining the magnetic anisotropy of a conductive wire or conductive tape of unlimited length from the positional dependence of critical current measurements in an applied magnetic field oriented at different angles to the conductive wire or conductive tape is also provided. The positional dependence of the critical current is measured with the strength of magnetic field B at a given magnitude and oriented a first angle to the conductive wire or conductive tape. The positional dependence of the critical current is then measured with the magnetic field (having the same magnitude) oriented at a second angle. The two measurements are then compared to determine the positional dependence of the magnetic anisotropy.

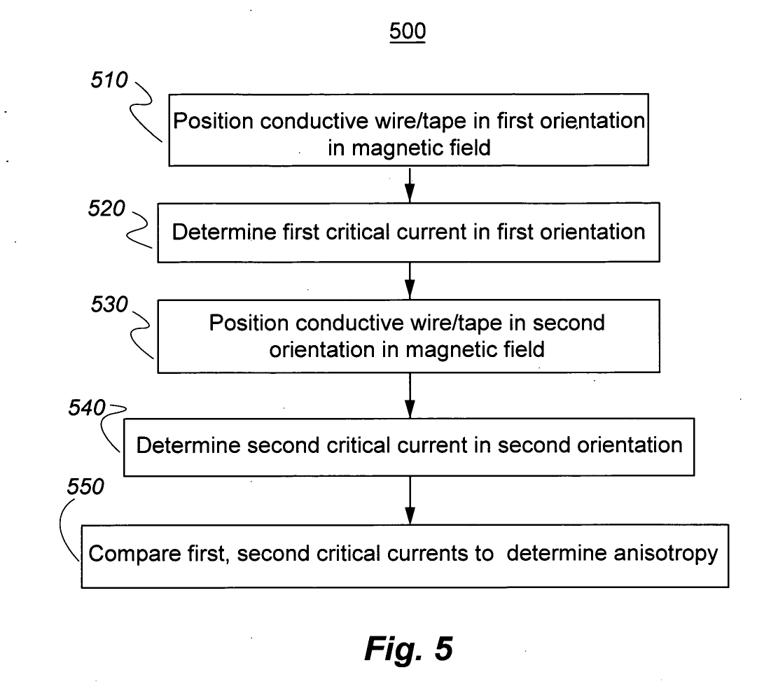

A flow chart outlining the steps of method 500 is shown in FIG. 5. Method 500 may be practiced in conjunction with apparatus 100, described hereinabove. In Step 510, conductive wire or conductive tape 130 is positioned in magnetic field B (FIGS. 1 and 2) with the current-carrying direction of conductive wire or conductive tape 130 parallel to the axis of rotation 120 of magnetic field generation assembly 110. As previously described, magnetic field B is generated by magnets 112, 114 of magnetic field generation assembly 110 and has a strength of about 0.5 Tesla. Conductive wire or conductive tape 130 is oriented such that a current I passing through a portion 136 of conductive wire or conductive tape 130 will be orthogonal to magnetic field B. A first critical current is determined while conductive wire or conductive tape 130 is positioned in the first orientation (Step 520). Conductive wire or conductive tape 130 is then positioned in a second orientation that is different from the first orientation (Step 530). As in the first position, conductive wire or conductive tape 130 is positioned in second orientation such that current I passing through conductive wire or conductive tape 130 will be orthogonal to magnetic field B. In Step 540, a second critical current is then determined while conductive wire or conductive tape 130 is positioned in the second orientation. The first critical current and the second critical current are then compared to determine the magnetic anisotropy of conductive wire or conductive tape 130 (Step 550). Method 500 may further include additional measurements of anisotropy as a function of angle through 120°-360°.

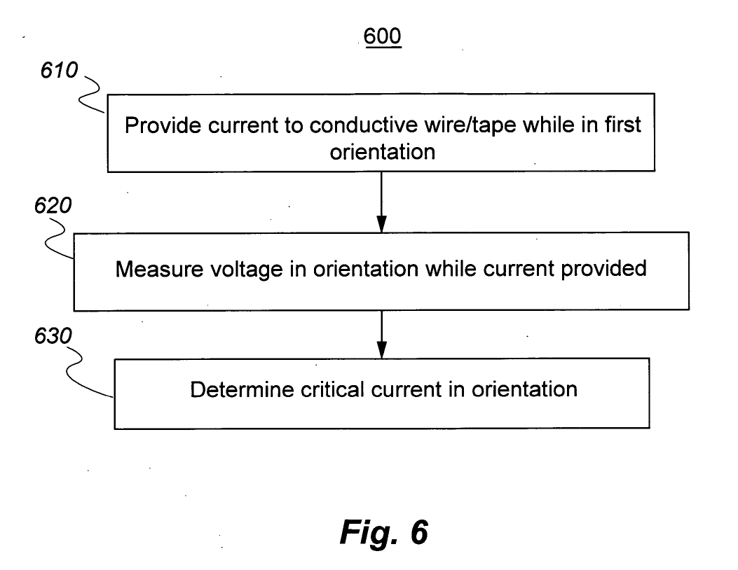

In one embodiment, at least one of the first critical current and the second critical current are determined by the method shown in FIG. 6. Method 600 may be practiced in conjunction with apparatus 100, described hereinabove. In Step 610, a current I is provided to conductive tape or conductive wire 130 while conductive tape or conductive wire 130 is positioned in the selected orientation. The current I is provided to that portion (136 in FIG. 2) of conductive wire or tape 130 that is positioned in magnetic field B. Current I is at least as great as the critical current of conductive wire or conductive tape 130. As current I is provided to conductive wire or conductive tape 130, the voltage between a first point 132 and second point 134 on conductive wire or conductive tape 140 is measured (Step 620), and the critical current is determined from the current I and voltage (Step 630).

In one embodiment, conductive tape or wire 130 is positioned in a selected orientation in magnetic field B by rotating magnetic field generation assembly 110 about axis 120 (FIGS. 3a, 3b). The magnetic field generation assembly 110 may be manually rotated, or may be rotated by drive mechanisms that are known in the art, as previously described. Alternatively, the orientation of conductive wire or conductive tape 130 may be set by rotating conductive wire or conductive tape 130 about axis 120. While the first orientation and second orientation typically differ by 45° or 90°, there is no limitation as to the angle between the different orientations.

High critical current densities in conductors comprising high temperature oxide superconductors such as YBCO are dependent upon different types of defects—also referred to as dopants or structures—and the density of such defects. Different film fabrication processes produce different microstructures, which in turn produce distinctly different pinning behaviors in applied magnetic fields. In addition, intentional inclusion of non-superconducting defects such as, for example, barium zirconate particles, may serve as a means of enhancing critical currents in superconducting wires and tapes. Such enhancement includes improving flux pinning and tailoring the properties of the conductive wire or conductive tape under temperature and magnetic field conditions encountered during operation. Intentionally included defects are typically contained in the superconducting portion of a conductive wire or conductive tape as a function of position (i.e., at predetermined positions) along the length of the conductive wire or conductive tape. In addition, the homogeneity of such superconducting wires and tapes may be characterized by measuring the critical current as a function of position—e.g., every 1 cm on conductive wires or conductive tapes having a length of two meters. However, because the crystal structure of a superconducting material determines its superconducting properties in applied magnetic fields, it is not clear that simply maintaining the critical current within some envelope is sufficient to prove that the properties are similarly maintained in a magnetic field or as a function of applied field angle. The ability to characterize the magnetic field anisotropy of the critical current as a function of position would provide the ability to demonstrate that a fabrication process is stable and capable of producing a superconducting wire or tape having uniform critical current and magnetic field properties.

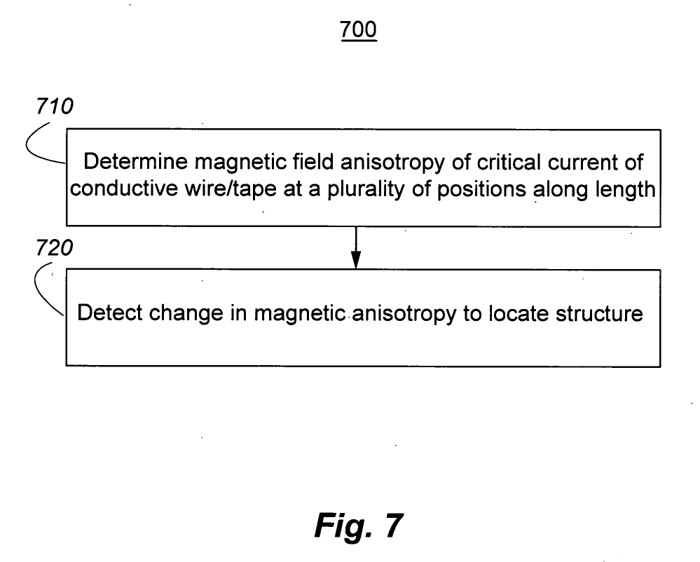

Accordingly, the invention also provides a method, a flow chart of which is shown in FIG. 7, of locating such structures in a conductive wire or a conductive tape. The two sets of data are then compared to determine the anisotropy. In Step 710, the magnetic anisotropy of the critical current of the conductive wire or conductive tape 130 is determined at a plurality of positions along the length of conductive wire or conductive tape 130. In one embodiment, the magnetic anisotropy is determined at each of the plurality of positions by method 600, previously described above. The critical current is typically first determined at the plurality of positions with the magnetic field in a first orientation. The magnetic field is then repositioned in a second orientation and the critical current is determined at the plurality of positions. The structure is then located—i.e., the position (or, in the case of multiple structures, positions)—by detecting changes in the magnetic field anisotropy of the critical current observed at the plurality of positions. The position-dependent measurements of critical current anisotropy may be compared to a known critical current anisotropy that has been determined from previous measurements made on short segments of conductive wire or conductive tape 130 made by the same process as that used to make the sample being studied.

In one embodiment, the magnetic anisotropy may be determined at each of the plurality of positions by translating the magnetic field generation assembly 110 along a track of finite length while conductive wire or conductive tape 130 is held stationary. In another embodiment, magnetic field generation assembly 110 remains stationary while conductive wire or conductive tape 130 is translated through magnetic field B by payout/take-up assembly 180. In a third embodiment, magnetic field generation assembly 110 is translated in one direction while conductive wire or conductive tape 130 is translated in the opposite direction.

Coated conductors characteristically carry higher super currents when a magnetic field is applied parallel to the crystallographic “ab” plane of the superconductor than when the field is applied parallel to the crystallographic “c” axis. This anisotropic behavior varies depending on the crystalline morphology of the YBCO as deposited on different metallic substrates and with different chemical additions. The accommodation of I_{c} introduces design complications where the conductor is employed in an application, yet the property serves as a diagnostic for the study of superconductors.

I_{c} anisotropy can be fully characterized as a function of angle in a “move and measure” manner where I_{c} is measured and one angle, the angle is changed incrementally and I is measured again through an angle 0<θ<360. Additionally the position dependence of the anisotropy could be characterized by performing the angular characterization at many positions along the length of a conductor. The limiting factor in characterization would be the time needed to make the angular measurements. To make a critical current determination at one position takes a unit of time, however to make a number, n, more determinations will, at a minimum take n times longer. To increase the speed of position dependent characterization, the capability to add additional stages was added to the measurement zone of the tape handling system. The additional stages permit magnetic fields to be oriented at different angles to the conductor and the voltage to be measured with an additional voltmeter. In this manner the anisotropy itself can be characterized by as many fields oriented at as many angles as necessary. One embodiment of the invention includes three stages to monitor simultaneously during an I_{c} measurement. The core principles that this technique relies on are that the I_{c} anisotropy is characteristic of a conductor produced by a fabrication process, and when that process is used to fabricate long conductors, the I_{c} anisotropy should be uniform along a conductor's length.

In addition to the electronics necessary to make critical current measurements, the measurement system consists of a conductor translation and positioning device, and measurement stages which utilize a cryogenic rotator, and, or a cryogenically compatible electro-magnet each with two voltage taps. A voltage tap located on either side of each magnetic field generating assembly contacts the conductor. The voltage drop across the region of the conductor subject to the generated fields between the two taps is recorded during I_{c} measurement.

The positioning device consists of a feed and a take-up reel and a measurement zone. It is used to translate the superconductor for position-dependent I_{c} measurements. The conductor is moved horizontally through the zone where the I_{c} is measured. The system can accommodate conductors from 1 to ˜100 m in length and can be programmed to step sizes of 1 cm or less. The translation system is used to mount and test measurement apparatuses under development.

The cryogenic rotator has two embodiments. In a first embodiment, the angular orientation of the magnetic field generated by permanent magnets is set by means of a stepper motor and mechanical gearing. In the second embodiment, the field angle is set by hand and held fixed with a set screw.

A mechanical rotator suitable for operation at cryogenic temperatures was constructed to measure the critical current as a function of an applied magnetic field angle, I_{c}(B,θ). In one embodiment, the device consists of a steel ring, which is slotted on the inner diameter to accept commercially available permanent magnets measuring, e.g., 25 mm×25 mm×13 mm. The magnets are held in the slots by their attraction to the iron ring and are oriented with the same polarity. The assembly produces a magnetic field adjustable over the range of, e.g., 0.30 T<B<0.53 T, for a measurement gap of 30 mm to 15 mm, respectively. A brass ring gear is mounted on the external diameter of the steel ring and is rotated about the tape by a worm gear attached to a planetary gear head driven by a stepper motor. The steel ring, magnet and brass gear assembly is supported in a housing, e.g., an aluminum housing, by bearings offset by 120° on an outer diameter. The elements of the device can be sized to accommodate the thermal contraction occurring during immersion in liquid nitrogen. One particular combination of a worm gear, gear head and stepper motor assembly resulted in a calculated ratio of 5.5 motor turns per 3.6° angular rotation. The stepper motor controller had a maximum step resolution of 25,000 steps/revolution, which resulted in a total angular resolution beyond that necessary to measure the anisotropy of I_{c}. The magnet rotator and drive system were relatively inexpensive as constructed in parts and machining costs in comparison to the cost of conventional rotators and magnet systems.

Magnetic field generation by permanent magnets offers the advantage of reducing cost and eliminating the complexity of instrumentation and experimentation introduced by generating a magnetic field using electric solenoids and power supplies. Commercially available Nd₂Fe₁₄B (rare earth) magnets were selected for magnetic field generation because of their field strength. Nd₂Fe₁₄B undergoes a spin re-orientation below 135 K, which results in a change in magnetic field as a function of temperature. Other rare earth magnets may be used as well. The possibility existed that the spin re-orientation would result in a magnetic field vector direction change as the magnets were cooled to 75 K. Comparison of angular response at 300 K and 75 K using a calibrated cryogenic Hall probe and rotating the magnet system through 390° at both temperatures indicated a decrease of 1% in the field magnitude. No shift in direction of the field maximum was observed.

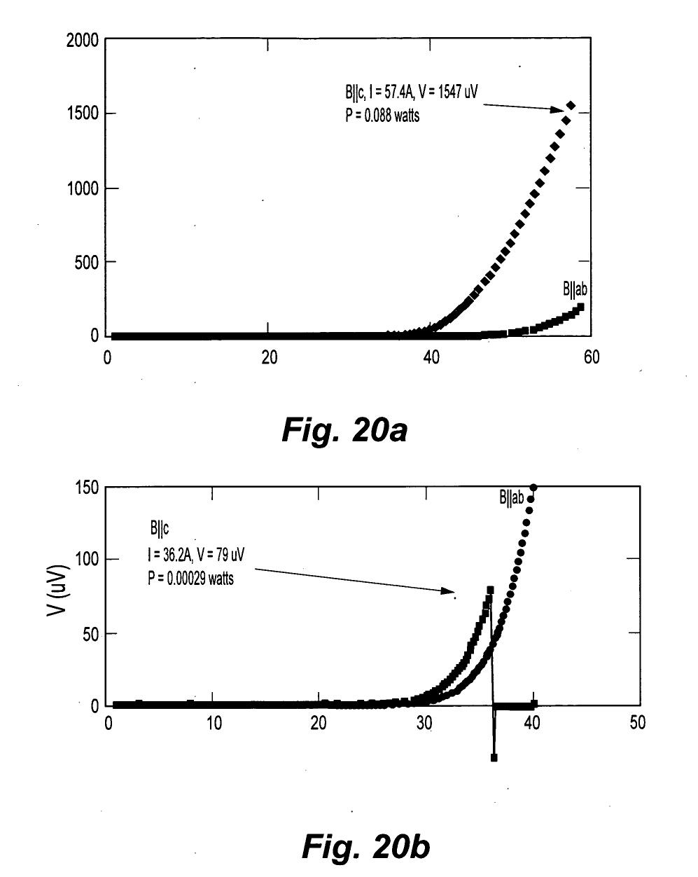

In one embodiment of the present invention, the Joule heating that can occur during bi-axial positional I_{c} characterization with an applied magnetic field can be controlled. FIG. 20(a) shows voltage-current curves measured at two positions simultaneously using a magnetic field applied at two different angles. The anisotropic nature of the superconductor wire was such that more current was carried by the position with the field oriented B∥ab than with the position B∥c. In order to measure the I_{c} of the B∥ab position, the current must be carried by the B∥c position as well. This can result in a potentially damaging condition of excessive heating in the tape at this position as I_{c} (B∥c) was 34 A while I_{c} (B∥ab) was 43 A.

On a different coated conductor, FIG. 20(b) shows the voltage-current curves measured at two positions simultaneously using a magnetic field applied at two different angles. An electromagnet was used to provide the field at one of the positions. The dissipation at the position with the field oriented B∥c was limited to 0.0029 watts by reducing the current in the electromagnet to zero. That allowed excessive heating in the tape at that position to be avoided.

The present invention is more particularly described in the following examples which are intended as illustrative only, since modifications and variations will be apparent to those skilled in the art.

### EXAMPLE #1

A magnet rotator was used to apply a magnetic field normal to the surface of a conductor to characterize the position dependence of I_{c}. I_{c} s at positions along the conductor were observed and identified which were outside the standard deviation for measurements along the length. The rotator was then used to investigate the angular dependence of I_{c} at these positions and in the regions close to these positions. Given prior knowledge of the superconducting characteristics material, the position dependence and the angular I_{c} results indicate the effectiveness of the processing technique used in producing the conductor.

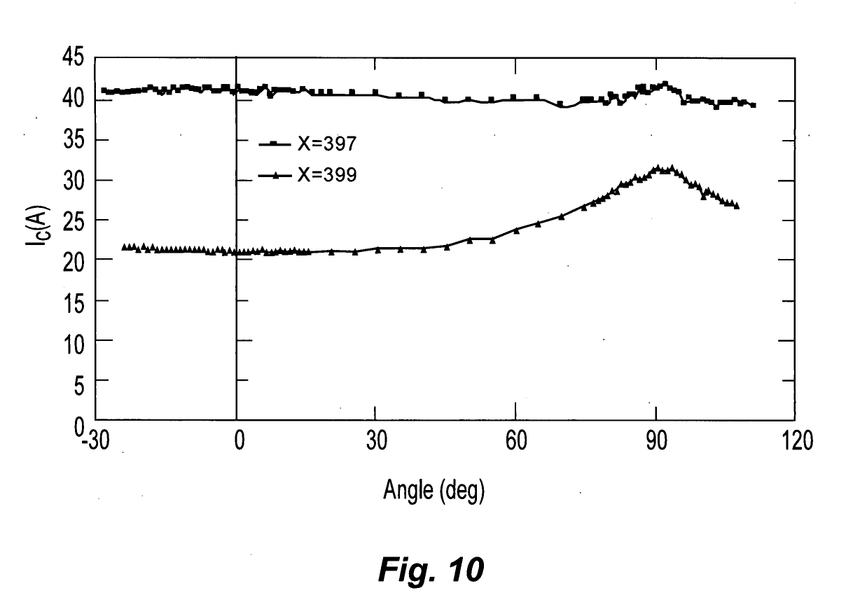

Position dependent I_{c} measurements were made on a 22-meter long conductor. The conductor was immersed in liquid nitrogen at a temperature of 75α. I_{c} measurements were made at the position on the conductor where a localized zone of magnetic field B=0.52 T over a length of 2 cm was applied parallel to the vector normal to the conductor surface using the magnet rotator described above. The conductor was translated through the zone in increments of 1 to 3 cm movements and a length of 20 meters intermediate to the overall length was characterized in this ‘move and measure’ manner. A region of interest located between x=395 cm and x=405 cm was identified (see FIG. 10) by the 20 ampere variation in critical current over a distance of 3 centimeters. The conductor was repositioned at the beginning of this variation and the rotator was used to make angular I_{c} measurements at positions within the region of variation.

Angular I_{c} results at the positions 397 and 399 show an overall decrease in magnitude I_{c} Additionally, the x=397 cm data show comparable I_{c}s at an angle of 0 degrees relative to 90 degrees varying from about 41 amperes to about 42 amperes. In contrast, the x=399 cm data differ in that the comparable I_{c}s values at an angle of 0 degrees relative to 90 degrees vary from about 21 amperes to about 32 amperes. The significance of the data taken at these two positions is that over a distance of 2 centimeters, the conductor characteristics change from a nominally isotropic material to an anisotropic material. The ratio of the I_{c}s at the two directions may also be compared: 0.976 vs 0.656. A purely isotropic material would exhibit a ratio of 1.

### EXAMPLE #2

To increase the speed of characterization, an additional measurement stage applying a local field at a different angle was added to the configuration in Example #1. This allowed the simultaneous measurement of two voltage/current curves with data taken at two magnetic field angles. The I_{c} anisotropy can then be characterized by calculating the ratio of the position dependence of I_{c} in a single series of conductor translations. Position dependent variations in this ratio serve to identify regions needing further characterization using the I_{c}(angle) capability of the rotator described above.

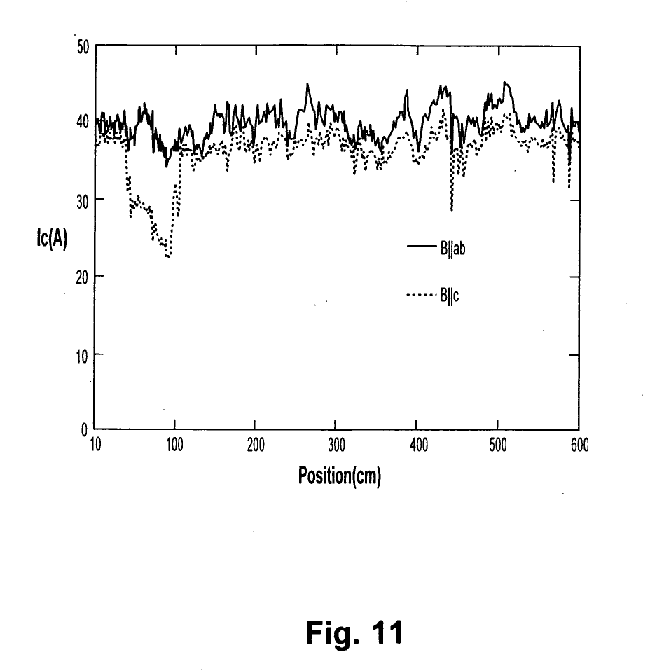

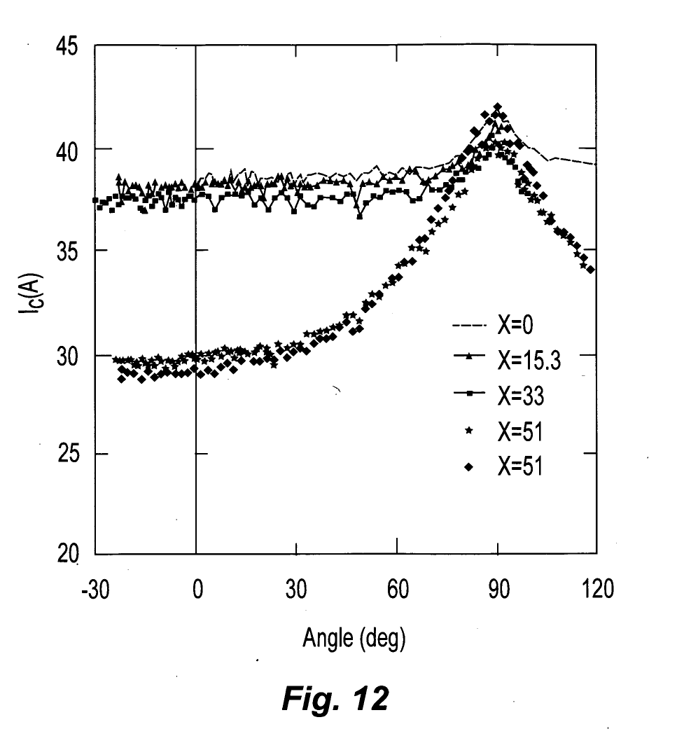

Position dependent I_{c} measurements were made on a 7-meter long conductor as described in Example #1, with the addition of a second rotatable magnet stage set at the fixed angle of 0 degrees. With the first stage set at 90 degrees and an additional voltmeter this second device permitted the characterization of I_{c}(B∥c) and I_{c}(B∥ab) to be performed in a single series of tape translations. This provided an increase in speed of at least a factor of two over a method whereby a conductor is translated and I_{c}(B∥c) is measured in one pass, the conductor is then returned to it's original position, the angle is reset B∥ab, and conductor is translated a second time. An increase in positioning accuracy is a second benefit of this method. Errors in tape translation occur incrementally instead of having an offset error introduced by repositioning between scans. Results are shown in FIG. 11. The I_{c} ratio described above was about 0.9 and therefore slightly lower than Example #1. Additionally there was a region starting at x˜40 cm and continuing down the conductor for about 60 cm where the ratio was about 0.75. This region of apparent anisotropy was investigated using the cryogenic rotator. The angular I_{c} results taken at positions X=0 cm, 15 cm, 33 cm, 51 cm, and 66 cm are shown in FIG. 12. It is clear that whatever the causes of variations in the I_{c} angular dependence, they occurred over a large distance, x˜60 centimeters. One could imagine that this would occur during fabrication startup, shutdown, or in the event of events like power surges and failures, etc. Additional significance of these data lies in considering the ease of identification of conductor non-uniformities, the causes of the I_{c} variations, and the ability to correlate superconductor characteristics with processing techniques. By incorporating a second measurement stage with the magnetic field oriented at a different angle, the I_{c} angular dependence can be characterized faster than can be done using the method where a position is fixed and I_{c}(angle) is measured, the tape is translated and I_{c}(angle) is characterized again. The incorporation of a second stage could be expanded to the incorporation of any number of stages, n, which would permit simultaneous measurement of I_{c1}(B, angle₁, X₁), I_{c2}(B, angle₂, X₂), . . . , I_{cn}(B, angleₙ, Xₙ).

### EXAMPLE #3

The incorporation of an additional measurement stage applying a magnetic field at an orientation to the conductor was accomplished by using a cryogenically compatible electromagnet. The adjustable magnetic field was used to study the local I_{c}(B) dependence of a region, X, located intermediate along the length of a larger conductor over which variations in the anisotropy ratio I_{c} angular dependence have been characterized.

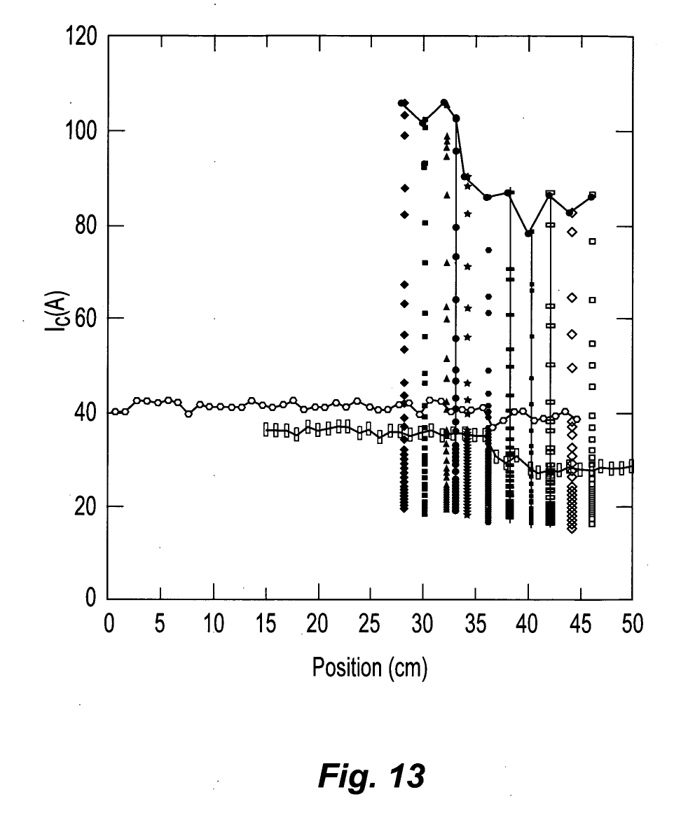

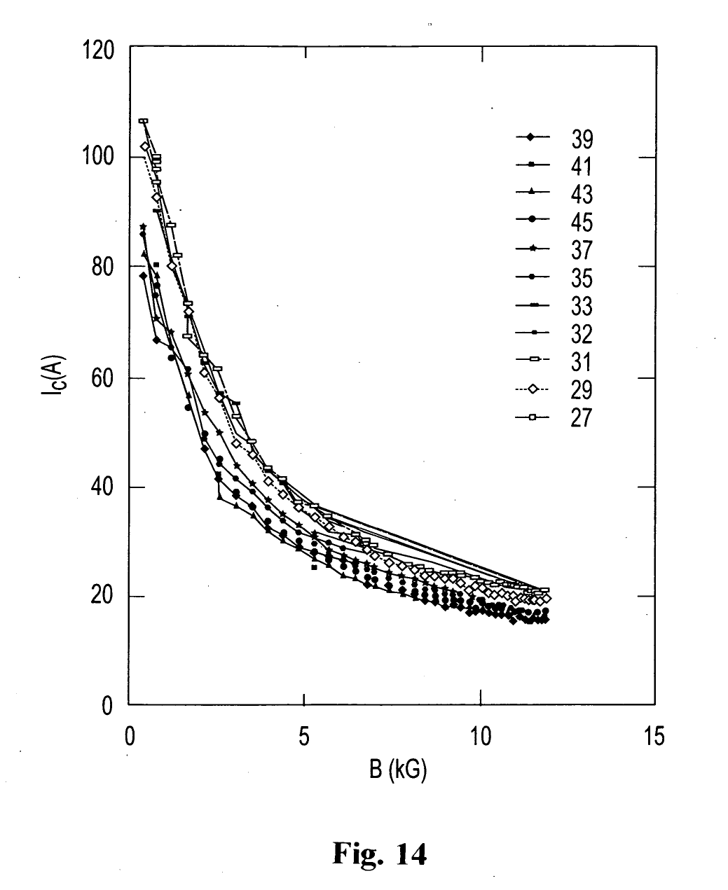

Position dependent I_{c} measurements were made on the 7-meter long conductor as discussed in Example #2. The magnetic field applied B∥c by the second stage was produced by an electromagnet capable of fields B<2 Teslas. During simultaneous acquisition of voltage current curves a predetermined current was applied to the magnet which produced a predetermined magnetic field B, B∥c. In this manner, the position dependence of the anisotropy ratio was characterized as previously mentioned. Additionally, at positions 25 cm≦X≦50 cm, where the ratio was seen to vary as a function of X, I_{c} as a function of magnetic field, I_{c}(B), measurements were performed. FIG. 13 contains both the position dependent I_{c} measurements in the directions B∥c B∥ab, and the I_{c}(B) measurements performed as a function of X. The vertical lines are the field dependences. FIG. 14 shows the many field dependences of I_{c}(B∥c) with the positions they were taken at listed vertically along the right side of the graph. The significance in this capability and data is in the ability of superconductor fabricators to design their conductors to include conduction enhancing chemistry in the fabrication that exhibits a particular I_{c} angular dependence. This angular dependence itself is dependent upon the magnetic field and temperature at which it is measured. One can visually separate the data in FIG. 14 into two groups of data each of which is associated with a position and an I_{c} anisotropy. This grouping is made more apparent by plotting the data by log I_{c} vs. log B. At magnetic fields below 5 kG the I_{c}(B) was especially divergent.

### EXAMPLE #4

The I_{c} magnetic field angular dependence was used to determine the magnetic field orientations in which a superconductor is preferentially conductive relative to the conduction direction and applied magnetic fields. This direction is determined relative to the conductor surface and length. The determination can be made without prior knowledge of conductor fabrication method.

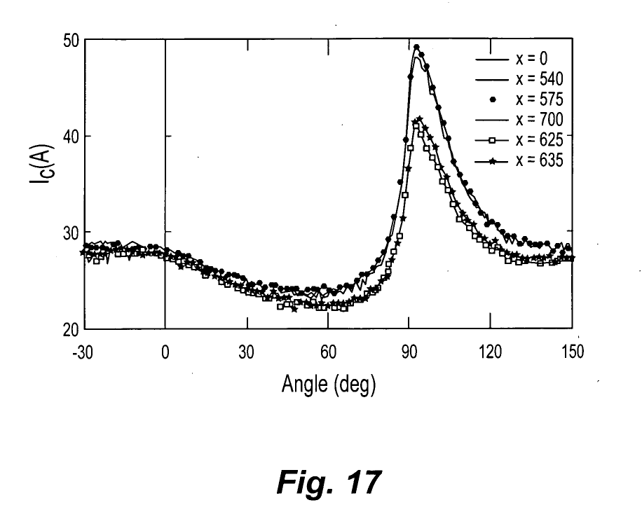

Position dependent I_{c} measurements using bi-axially applied magnetic fields as in Example #3 were made along a length of superconductor immersed in liquid nitrogen. The measurements indicated a region of interest located approximately 620 centimeters from the leading end. This region was investigated by conducting a series of I_{c}(angle) measurements at the positions listed in FIG. 17. The characterization revealed a consistent ‘tilted’ I anisotropy relative to the tape surface normal vector. This is manifested by a peak in the I_{c} at an angle other than 90 degrees. Additionally the angular characterization shows that the off axis peak varied in intensity as a function of position and that this variation correlates with the bi-axially applied magnetic field data initially used to identify the region of interest. The significance of the identification of the direction of tilted angular conductivity lies in considering electrical applications of superconductors where magnetic fields are applied at various angles to the conductor.

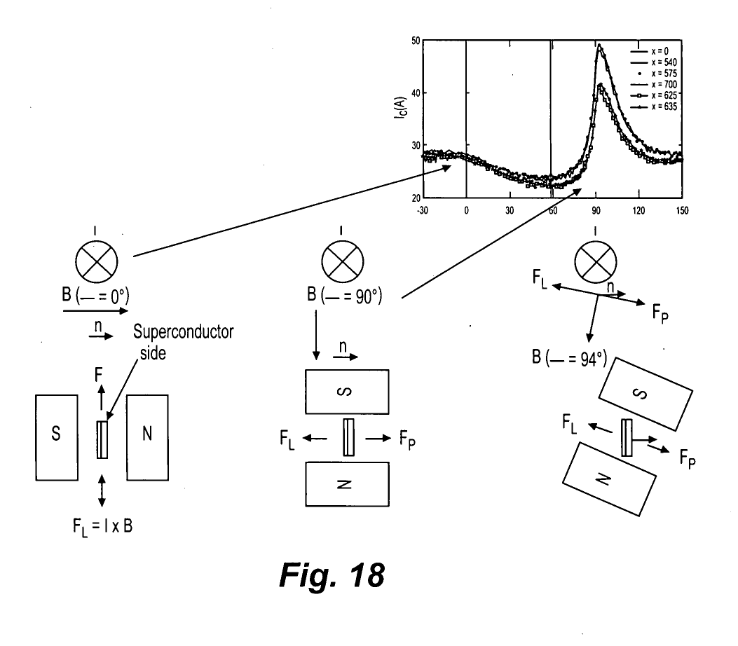

As shown in FIG. 18, the current direction in the conductor, in combination with the applied field direction defines the Lorentz force direction. The pinning force is defined as the negative of the Lorentz force at I_{c}. The asymmetry in I_{c} indicated by the angular measurements gives a direct indication of the preferential conduction direction without the need to trace properties back to the wire fabricator. This method of determining the maximum conduction direction can be used to optimize the winding direction of the superconductor in electrical applications.

Consider the case of a wire or cable carrying current. Circumferential magnetic fields are generated orthogonal to the current direction. If superconducting tape is used to wind the cable and the tape surface is oriented in the radial direction, the magnetic fields are nominally parallel to the ab crystallographic plane of the superconductor. At currents approaching the critical current of the superconductor the resultant field affects the conductivity of the conductor. Under the condition where the field vector is slightly off axis to the conduction planes, at currents approaching I_{c}, the conductor will exhibit different amounts of power dissipation depending on the direction of magnetic field. Knowing the exact nature of the asymmetric anisotropy will allow the conductor to be optimized for conduction. In the condition where alternating currents generate alternating fields about a cable. Electrical currents of magnitude close to I_{c} will result in different losses depending on the direction of the current. Thus a conductor would experience power losses during a part of the alternating current cycle. Knowing the exact nature of the asymmetric anisotropy will allow the conductor to be optimally wound for electrical conduction.

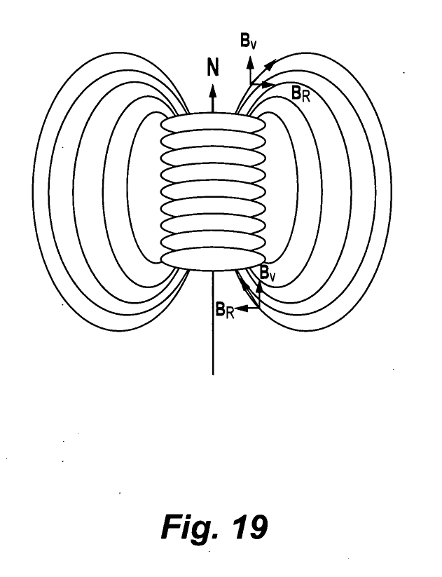

Another case to consider is the common solenoid and generating a magnetic field B with vectoral components B_{R} and B_{y} depicted in FIG. 19. Vectoral components of magnetic fields along the length of a solenoid wound using superconducting tape with asymmetric anisotropy will affect the conduction of the superconductor. At the ends of the solenoid, the field vectors diverge radially and with vectoral components, B_{R} in opposite radial directions at the ends of the solenoid whereas in the center the field vector is nominally parallel to the length of the solenoid. Thus a solenoid wound using superconductor with tilted I_{c}(B) anisotropy can exhibit different conductivity at positions intermediate to the length and symmetric about the center. A magnet designer using the knowledge of the asymmetric I_{c} anisotropy could optimize the winding of the solenoid to maximize the magnetic field generated.

While typical embodiments have been set forth for the purpose of illustration, the foregoing description should not be deemed to be a limitation on the scope of the invention. Accordingly, various modifications, adaptations, and alternatives may occur to one skilled in the art without departing from the spirit and scope of the present invention.

1. An apparatus for measuring magnetic anisotropy of a conductive tape or a conductive wire, the apparatus comprising:
a magnetic field generation assembly, the magnetic field generation assembly comprising a plurality of magnets that are fixed with respect to each other and rotatable about an axis, wherein the plurality of magnets is capable of generating a uniform magnetic field orthogonal to a direction of a current passing through a portion of the conductive wire or the conductive tape located along the axis, and wherein the uniform magnetic field is rotatable about the axis;
a power supply electrically connected to the conductive wire or the conductive tape, wherein the power supply is capable of providing current to the conductive wire or the conductive tape; and
a voltage measurement device capable of measuring a voltage between a first point and a second point of the conductive wire or the conductive tape, wherein the portion of the conductive wire or the conductive tape is located along the axis between the first point and the second point.

2. The apparatus according to claim 1, further including an assembly for moving the conductive wire or the conductive tape through the magnetic field generation assembly.

3. The apparatus according to claim 1, wherein at least one of the plurality of magnets is a rare earth magnet.

4. The apparatus according to claim 1, further including a low temperature bath, the low temperature bath being capable of maintaining the magnetic field generation assembly and the portion of the conductive wire or the conductive tape at a temperature at or below the boiling point of nitrogen.

5. The apparatus according to claim 1, wherein the power supply is one of a DC power supply, an AC power supply, and a pulsed power supply that is capable of providing a current to the conductive wire or the conductive tape that is greater than or equal to the critical current of the conductive wire or the conductive tape.

6. A magnetic field generation assembly for measuring positionally dependent anisotropy along a length of a conductive wire or a conductive tape of greater than about one meter, the magnetic field generation assembly comprising:
a ring having an inner surface; and
a pair of magnets disposed on the inner surface of the ring, wherein the pair of magnets are rotatable about an axis of the ring and are diametrically opposed to each other, wherein the pair of magnets is capable of generating a uniform magnetic field orthogonal to a direction of a current in a portion of the conductive wire or the conductive tape disposed at the axis, and wherein the uniform magnetic field is rotatable about the axis.

7. The magnetic field generation assembly according to claim 6, further including a drive mechanism coupled to the ring, wherein the drive mechanism rotates the ring about the axis.

8. An apparatus for measuring magnetic anisotropy of a conductive tape or a conductive wire, the apparatus comprising:
a magnetic field generation assembly comprising a ring having an inner surface; and a pair of magnets disposed on the inner surface of the ring, wherein the pair of magnets are diametrically opposed to each other and rotatable about an axis of the ring, wherein the pair of magnets is capable of generating a uniform magnetic field orthogonal to a direction of a current in a portion of the conductive wire or the conductive tape disposed along the axis, and wherein the uniform magnetic field is rotatable about the axis;
a power supply electrically connected to the conductive wire or the conductive tape, wherein the power supply provides the current through one of the conductive wire and the conductive tape;
a voltage measurement device capable of measuring a voltage between a first point and a second point of the conductive wire or the conductive tape, wherein the portion of the conductive wire or the conductive tape is located along the axis between the first point and the second point; and
a pay-out/take-up system for translating the conductive wire or the conductive tape through the magnetic field generation assembly.

9. The apparatus of claim 8 comprising at least two of said magnetic field generation assemblies whereby position dependent I_{c} anisotropy characterization can be simultaneously conducted at multiple positions under varying magnetic fields and angles.

10. The apparatus of claim 8 further comprising an electromagnetic field generation assembly coupled to a controller capable of turning the electromagnetic field on and off at predetermined intervals.

11. The apparatus of claim 9 further comprising an electromagnetic field generation assembly coupled to a controller capable of turning the electromagnetic field on and off at predetermined intervals.

12. A method of determining the magnetic anisotropy of a conductive wire or a conductive tape of a length of greater than about one meter, the method comprising:
positioning the conductive wire or the conductive tape in a magnetic field having a predetermined strength in a first orientation with respect to the magnetic field such that a current passing through the conductive wire or the conductive tape is orthogonal to the magnetic field;
determining a first critical current of the conductive wire or conductive tape in the first orientation;
positioning the conductive wire or the conductive tape at a second orientation relative to the magnetic field;
determining a second critical current of the conductive wire or conductive tape in the second orientation; and
comparing the first critical current to the second critical current to determine the magnetic anisotropy of the conductive wire or conductive tape.

13. The method according to claim 12, wherein determining the first critical current of the conductive wire or conductive tape in the first orientation comprises:
providing the current to the conductive wire or conductive tape while the conductive wire or conductive tape is in the first orientation;
measuring a first potential between a first point and a second point of the conductive wire or the conductive tape, wherein the portion of the conductive wire or the conductive tape positioned in the magnetic field is located between the first point and the second point, while the conductive wire or conductive tape is in the first orientation and while the current is provided to the conductive wire or conductive tape; and
determining the first critical current of the conductive wire or conductive tape in the first predetermined orientation from the first potential and the magnetic field.

14. The method according to claim 12, wherein determining the second critical current of the conductive wire or conductive tape in the second orientation comprises:
providing the current to the conductive wire or conductive tape while the conductive wire or conductive tape is in the second orientation;
measuring a second potential between the first point and the second point of the conductive wire or the conductive tape, wherein the portion of the conductive wire or the conductive tape positioned in the magnetic field is located between the first point and the second point, while the conductive wire or conductive tape is in the second orientation and while the current is provided to the conductive wire or conductive tape; and
determining the second critical current of the conductive wire or conductive tape in the second orientation from the second potential and the magnetic field.

15. A method for detecting regions, within a conductive wire or conductive tape, having a critical current that varies from the average critical current by a predetermined value, the method comprising:
determining a magnetic field anisotropy of the critical current of the conductive wire or the conductive tape at a plurality of positions along a length of the conductive wire or conductive tape, wherein the regions can be identified within the conductive wire or the conductive tape as a function of position along the length; and
locating the regions by detecting a predetermined variance in the magnetic field anisotropy measured at the plurality of positions.

16. The method according to claim 15, wherein determining the magnetic field anisotropy of the critical current at each of the plurality of positions comprises:
positioning the conductive wire or the conductive tape in a magnetic field having a predetermined strength in a first orientation with respect to the magnetic field such that a current passing through the conductive wire or the conductive tape is orthogonal to the magnetic field;
determining a first critical current of the conductive wire or conductive tape in the first orientation;
positioning the conductive wire or the conductive tape at a second orientation relative to the magnetic field;
determining a second critical current of the conductive wire or conductive tape in the second orientation; and
comparing the first critical current to the second critical current to determine the magnetic field anisotropy of the conductive wire or conductive tape at each of the plurality of positions.

17. The method according to claim 16, wherein determining the first critical current of the conductive wire or conductive tape in the first orientation comprises:
providing the current to the conductive wire or conductive tape while the conductive wire or conductive tape is in the first orientation;
measuring a first potential between a first point and a second point of the conductive wire or the conductive tape, wherein the portion of the conductive wire or the conductive tape positioned in the magnetic field is located between the first point and the second point, while the conductive wire or conductive tape is in the first orientation and while the current is provided to the conductive wire or conductive tape; and
determining the first critical current of the conductive wire or conductive tape in the first predetermined orientation from the first potential and the magnetic field.

18. The method according to claim 16, wherein determining the second critical current of the conductive wire or conductive tape in the second orientation comprises:
providing the current to the conductive wire or conductive tape while the conductive wire or conductive tape is in the second orientation;
measuring a second potential between the first point and the second point of the conductive wire or the conductive tape, wherein the portion of the conductive wire or the conductive tape positioned in the magnetic field is located between the first point and the second point, while the conductive wire or conductive tape is in the second orientation and while the current is provided to the conductive wire or conductive tape; and
determining the second critical current of the conductive wire or conductive tape in the second orientation from the second potential and the magnetic field.

19. A method of controlling localized conductor power dissipation in a conductive wire or a conductive tape of a length of greater than about one meter at currents above I_{c} comprising:
simultaneously measuring position dependent I_{c} anisotropy at multiple positions, magnetic fields and angles by passing the conductive wire or tape through at least two magnetic field generation assemblies including at least one electromagnetic field generation assembly whereby position dependent I_{c} anisotropy characterization can be simultaneously conducted at multiple positions under varying magnetic fields and angles; and,
controlling localized conductor power dissipation in the conductive wire tape by adjusting the current of the electromagnetic field generation assembly.

20. A method of optimizing winding direction for conductivity of a superconductive wire or tape in a device comprising:
measuring I_{c} anisotropy of a superconductive wire or tape so as to determine any asymmetric I_{c} anisotropy; and,
selecting the winding direction for a device by use of the measured asymmetric I_{c} anisotropy in the superconductive wire or tape.

21. A method of measuring either position dependent I_{c} magnetic field anisotropy or position dependent I_{c} magnetic field dependence in a conductive wire or a conductive tape of a length of greater than about one meter comprising passing the conductive wire or tape through at least two of magnetic field generation assemblies whereby position dependent I_{c} anisotropy characterization can be simultaneously conducted at multiple positions under varying magnetic fields and angles.

22. The method of claim 21 wherein the at least two of magnetic field generation assemblies includes at least one electromagnetic field generation assembly.
